(19) United States
(12) Patent Application Publication
(10) Pub. No.: US 2026/0024825 A1
(43) Pub. Date: Jan. 22, 2026

(54) BATTERY MANAGEMENT SYSTEM AND A METHOD OF OPERATING THE SAME

(71) Applicants: HYUNDAI MOTOR COMPANY, Seoul (KR); KIA CORPORATION, Seoul (KR)

(72) Inventors: Eunhwan Kang, Hwaseong-si (KR); Ki Seung Baek, Hwaseong-si (KR); Jonghu Yoon, Hwaseong-si (KR); Jonghyun Park, Hwaseong-si (KR); Hwanseok Kim, Hwaseong-si (KR); Hee Taek Kim, Hwaseong-si (KR); Hyun Soo Park, Hwaseong-si (KR); HeeSung Moon, Hwaseong-si (KR)

(73) Assignees: HYUNDAI MOTOR COMPANY, Seoul (KR); KIA CORPORATION, Seoul (KR)

(21) Appl. No.: 19/176,422

(22) Filed: Apr. 11, 2025

(30) Foreign Application Priority Data
Jul. 22, 2024 (KR) 10-2024-0096690

(51) Int. Cl. H01M 10/42; G01R 31/36; G01R 31/396; H02H 7/18

(52) U.S. Cl. CPC H01M 10/425; G01R 31/3644; G01R 31/396; H02H 7/18; H01M 2010/4271

(57) ABSTRACT

A battery management system (BMS) includes at least one sensing unit configured to sense a state of at least one battery module, and a controller linked with the at least one sensing unit, wherein, when an abnormality occurs in the at least one sensing unit, the controller performs a hardware reset on the at least one sensing unit.

### CROSS-REFERENCE TO RELATED PATENT APPLICATION

This application claims priority to Korean Patent Application No. 10-2024-0096690, filed Jul. 22, 2024, the entire disclosure of which is hereby incorporated by reference.

### BACKGROUND

### Technical Field

The present disclosure relates to a battery management system and a method of operating the same, and more particularly to a battery management system (BMS) configured to control a high-voltage battery used in an electric vehicle, and the like, and a method of operating the same.

### Description of the Related Art

There has been growing interest in “Fail Safe Design” to prevent failure from spreading throughout the entire vehicle in the event of failure of a particular component of the electric vehicle.

A BMS, which safely protects a battery by measuring a cell voltage and temperature of a high-voltage battery of an electric vehicle, intermittently or permanently fails to measure a voltage and temperature of a battery cell in certain situations such as electrical disturbances, and thus a “cell voltage measurement recovery robustness strategy” is of major interest.

In the case of conventional technology, when a momentary communication line disturbance occurs during a process of measuring a voltage and temperature of a battery cell through a sensing chip (sensing IC) of a BMS, the conventional technology uses a method of initializing the sensing chip by performing a software reset thereon and measuring the voltage and temperature of the battery cell again.

However, when a momentary surge current and/or strong electrical disturbance affects the sensing chip, the sensing chip enters an abnormal mode state (e.g., STUCK state), and in this case, there is a problem that normal recovery may be permanently impossible by a software reset alone.

### SUMMARY

Therefore, the present disclosure has been made in view of the above problems, and it is an object of the present disclosure to provide a BMS configured to perform a hardware reset on a sensing chip of the BMS to restore the sensing chip to a normal state when an abnormality occurs in the sensing chip, and a method of operating the same.

It is another object of the present disclosure to provide a BMS configured to restore a sensing unit of the BMS to a normal state by a controller interrupting communication with the sensing unit when an abnormality occurs in the sensing unit, and a method of operating the same.

Objects of the present disclosure are not limited to the above-mentioned object, and other objects and advantages of the present disclosure, which are not mentioned, should be understood through the following description, and should become apparent from embodiments of the present disclosure. It is also to be understood that the objects and advantages of the present disclosure may be realized by means and combinations thereof set forth in the appended claims.

In accordance with an aspect of the present disclosure, the above and other objects can be accomplished by the provision of a BMS comprising at least one sensing unit configured to sense a state of at least one battery module, and a controller linked with the at least one sensing unit, wherein, when an abnormality occurs in the at least one sensing unit, the controller performs a hardware reset on the at least one sensing unit.

The BMS may further comprise a communication unit configured to communicate with the at least one sensing unit and the controller and links the at least one sensing unit with the controller, wherein, when an abnormality occurs in the at least one sensing unit, the controller performs a control operation so that the communication unit interrupts communication with the at least one sensing unit.

In accordance with another aspect of the present disclosure, there is provided a BMS comprising at least one battery module, a cell monitoring unit (CMU) comprising at least one sensing chip configured to sense a state of the at least one battery module, and a battery management unit (BMU) comprising a communication chip configured to communicate with the at least one sensing chip, and a control chip linked with the at least one sensing chip through the communication chip, wherein, when an abnormality occurs in the at least one sensing chip, the control chip performs a hardware reset on the at least one sensing chip.

When an abnormality occurs in the at least one sensing chip, the control chip may perform a control operation so that the communication chip interrupts communication with the at least one sensing chip.

In accordance with yet another aspect of the present disclosure, there is provided a method of operating the BMS comprising detecting, by a controller, an abnormality of at least one sensing unit configured to sense a state of at least one battery module, and performing, by the controller, a hardware reset on the at least one sensing unit.

The performing a hardware reset may comprise performing, by the controller, a control operation to interrupt communication with the at least one sensing unit.

The method may further comprise performing, by the controller, a software reset on the at least one sensing unit.

In accordance with yet another aspect of the present disclosure, there is provided a method of operating the BMS comprising detecting, by a control chip of a BMU, an abnormality of a sensing chip of at least one CMU configured to sense a state of at least one battery module, and performing, by the control chip, a hardware reset on the sensing chip.

The performing a hardware reset may comprise performing, by the control chip, a control operation to interrupt communication with the sensing chip.

The method may further comprise performing, by the control chip, a software reset on the sensing chip.

### BRIEF DESCRIPTION OF THE DRAWINGS

The above and other objects, features and other advantages of the present disclosure should be more clearly understood from the following detailed description taken in conjunction with the accompanying drawings, in which:

FIG. 1 is a configuration diagram of a BMS according to an embodiment of the present disclosure;

FIG. 2 is a diagram for describing an abnormality occurring in a sensing unit of the BMS according to an embodiment of the present disclosure;

FIG. 3 is a diagram for describing a failure response method according to conventional technology;

FIG. 4 is a flowchart of a method of operating the BMS according to an embodiment of the present disclosure;

FIG. 5 is a diagram for describing a failure response method of the BMS according to an embodiment of the present disclosure;

FIG. 6 is a diagram for describing communication interruption in the sensing unit of the BMS according to an embodiment of the present disclosure; and

FIG. 7 is a hardware reset timing chart of the sensing unit of the BMS according to an embodiment of the present disclosure.

### DETAILED DESCRIPTION

Hereinafter, reference is made in detail to embodiments of the present disclosure, examples of which are illustrated in the accompanying drawings and described below, and wherever possible, the same or similar elements are denoted by the same reference numerals even though they are depicted in different drawings and a redundant description thereof has thus been omitted. In the following description of the embodiments, suffixes, such as “module”, and “part”, are provided or used interchangeably merely in consideration of ease in statement of the specification, and do not have meanings or functions distinguished from one another. In the following description of the embodiments of the present disclosure, a detailed description of known functions and configurations incorporated herein have been omitted when it may make the subject matter of the present disclosure rather unclear. Further, the accompanying drawings are exemplarily given to describe the embodiments of the present disclosure, and should not be construed as being limited to the embodiments set forth herein, and it should be understood that the embodiments of the present disclosure are provided only to completely disclose the inventive concept and cover modifications, equivalents or alternatives which come within the scope and technical range of the disclosure.

In the following description of the embodiments, terms, such as “first” and “second”, are used only to describe various elements, and these elements should not be construed as being limited by these terms. These terms are used only to distinguish one element from other elements.

When an element or layer is referred to as being “connected to” or “coupled to” another element or layer, it may be directly connected or coupled to the other element or layer, or intervening elements or layers may be present. In contrast, when an element or layer is referred to as being “directly connected to” or “directly coupled to” another element or layer, there may be no intervening elements or layers present.

When a component, device, element, or the like of the present disclosure is described as having a purpose or performing an operation, function, or the like, the component, device, or element should be considered herein as being “configured to” meet that purpose or to perform that operation or function.

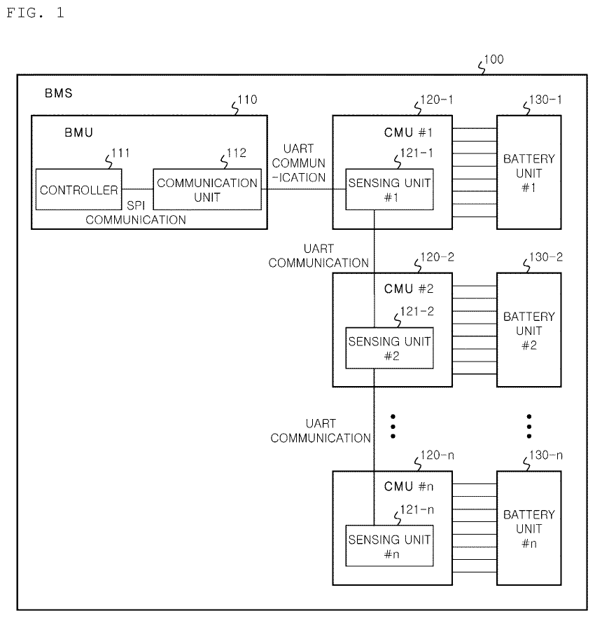

Hereinafter, a BMS and a method of operating the same according to the present disclosure is described in detail with reference to FIGS. 1-7.

FIG. 1 is a configuration diagram of the BMS according to an embodiment of the present disclosure.

Referring to FIG. 1, a BMS 100 according to an embodiment of the present disclosure includes a battery management unit (BMU) 110, at least one cell monitoring unit (CMU) 120-1, 120-2, . . . , 120-n, at least one battery module or unit 130-1, 130-2, . . . , 130-n, and the like.

Each of the battery modules 130-1, 130-2, . . . , 130-n is a battery assembly in which one or more battery cells (for example, 32 battery cells) is connected in series and/or parallel.

The CMUs 120-1, 120-2, . . . , 120-n are devices that monitor battery cells included in the battery modules 130-1, 130-2, . . . , 130-n.

For example, the CMUs 120-1, 120-2, . . . , 120-n include sensing units 121-1, 121-2, . . . , 121-n, respectively, and the sensing units 121-1, 121-2, . . . , 121-n sense states of the battery modules or units 130-1, 130-2, . . . , 130-n by sensing a voltage, a temperature, and the like of one or more battery cells included in the battery modules 130-1, 130-2, . . . , 130-n.

For reference, the sensing units 121-1, 121-2, . . . , 121-n may be implemented as sensing chips (sensing integrated circuits, or ICs).

The BMU 110 is a device that manages the at least one CMU 120-1, 120-2, . . . , 120-n.

For example, the BMU 110 includes a controller 111 and a communication unit 112. The controller 111 is linked with the communication unit 112 through, for example, serial peripheral interface (SPI) communication, and the communication unit 112 is linked with the at least one sensing unit 121-1, 121-2, . . . , 121-n through, for example, universal asynchronous receiver/transmitter (UART) communication, so that the controller 111 detects and controls the states of the at least one battery module 130-1, 130-2, . . . , 130-n through the at least one sensing unit 121-1, 121-2, . . . , 121-n, thereby managing the at least one CMU 120-1, 120-2, . . . , 120-n.

For reference, the controller 111 may be implemented as a central processing unit (CPU), and the communication unit 112 may be implemented as a communication chip that performs SPI and UART communication.

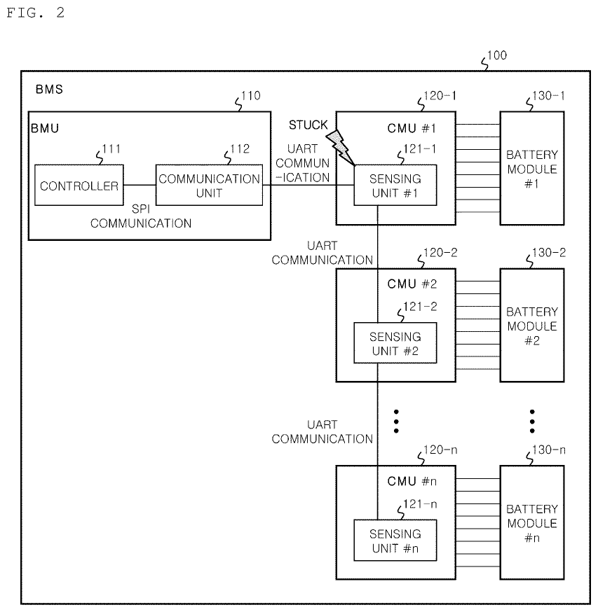

In a process in which the at least one sensing unit 121-1, 121-2, . . . , 121-n measures a voltage, a temperature, and the like of a battery cell included in the at least one battery module 130-1, 130-2, . . . , 130-n, a momentary surge current and/or strong electrical disturbance may cause the at least one sensing unit 121-1, 121-2, . . . , 121-n to enter an abnormal mode state (STUCK state), which is illustrated in FIG. 2.

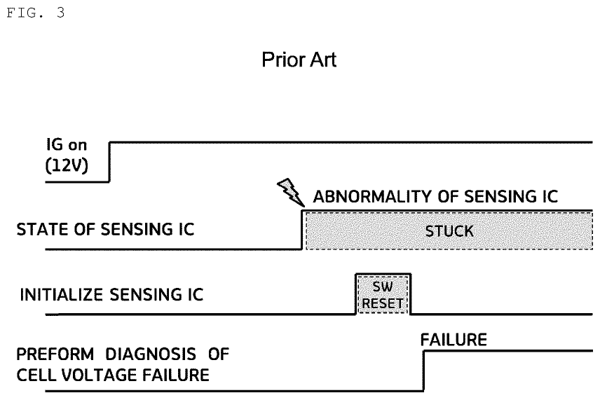

In this case, conventional technology has used a method of initializing a sensing unit by performing a software reset. In relation thereto, FIG. 3 illustrates a method of responding to failure of the BMS according to the conventional technology.

Referring to FIG. 3, in the case of the conventional technology, when an abnormality occurs in the sensing unit (sensing IC) due to a momentary surge current and/or strong electrical disturbance while an ignition device is turned on (IG on), the sensing unit enters an abnormal mode state (STUCK state) and the controller performs a software reset on the sensing unit. However, since the software reset of the sensing unit alone does not permanently restore the sensing unit to normal, a final diagnosis necessarily is cell voltage failure.

In this instance, when a hardware reset is performed directly on the sensing unit while the vehicle is in motion, a risk to a driver may be increased. Therefore, in the present disclosure, the sensing unit is safely restored by indirectly performing a hardware reset by controlling power of the sensing unit.

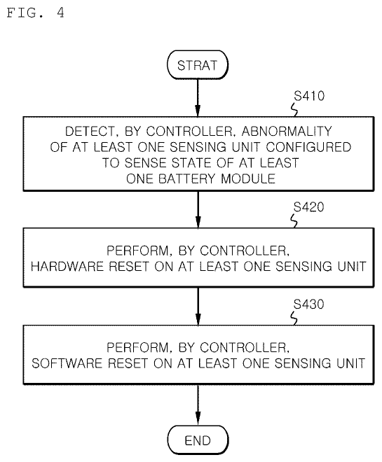

Hereinafter, a description is given of a failure response method of the BMS according to the present disclosure with reference to FIGS. 4-7.

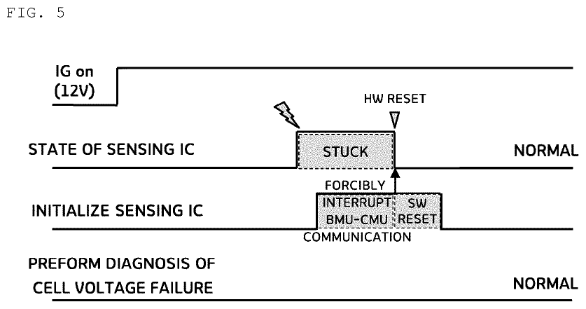

FIG. 4 is a flowchart of a method of operating the BMS according to an embodiment of the present disclosure. FIG. 5 is a diagram for describing a failure response method of the BMS according to an embodiment of the present disclosure.

Referring to FIGS. 4 and 5, when an abnormality occurs in the at least one sensing unit 121-1, 121-2, . . . , 121-n due to a momentary surge current and/or strong electrical disturbance while the ignition device is turned on (IG on), the at least one sensing unit 121-1, 121-2, . . . , 121-n enters an abnormal mode state (STUCK state), and the controller 111 detects this situation (see step S410).

When the controller 111 detects an abnormality in at least one sensing unit 121-1, 121-2, . . . , 121-n, the controller 111 controls the communication unit 112 so that communication between the communication unit 112 and the at least one sensing unit 121-1, 121-2, . . . , 121-n is forcibly interrupted, thereby performing a hardware reset on the at least one sensing unit 121-1, 121-2, . . . , 121-n (see step S420).

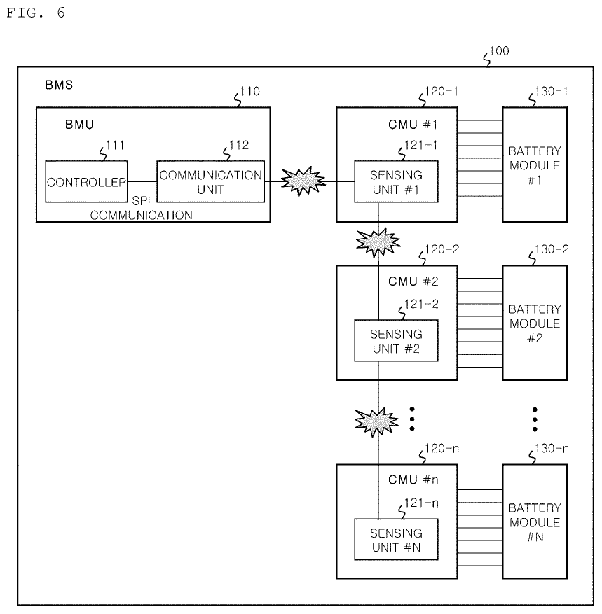

In relation thereto, FIG. 6 illustrates communication interruption in the sensing unit of the BMS according to an embodiment of the present disclosure. When communication between the BMU 110 and the at least one CMU 120-1, 120-2, . . . , 120-n is interrupted, the at least one sensing unit 121-1, 121-2, . . . , 121-n is powered off, causing a hardware reset and escaping from the abnormal mode state (STUCK state).

Thereafter, the controller 111 controls the communication unit 112 so that communication between the communication unit 112 and the at least one sensing unit 121-1, 121-2, . . . , 121-n is restored, and performs a software rest on the at least one sensing unit 121-1, 121-2, . . . , 121-n (see step S430) so that the at least one sensing unit 121-1, 121-2, . . . , 121-n operates in a normal state.

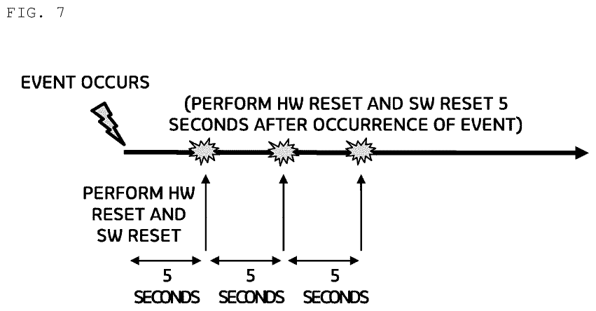

FIG. 7 is a hardware reset timing chart of the sensing unit of the BMS according to an embodiment of the present disclosure.

Referring to FIG. 7, when an abnormality occurs (event is issued) in the sensing units 121-1, 121-2, . . . , 121-n due to a momentary surge current and/or strong electrical disturbance, the controller 111 performs a hardware reset and a software reset after a certain period of time (for example, 5 seconds) has elapsed, taking into account a situation in which cell voltage measurement may not be possible due to noise or momentary connector contact failure.

When the sensing units 121-1, 121-2, . . . , 121-n are not normally restored even after performing a hardware reset and a software reset, the controller 111 performs a hardware reset and a software reset again after a certain period of time (for example, 5 seconds) has elapsed, and this process is repeated a preset number of times (for example, 3 times). Then, when the sensing units 121-1, 121-2, . . . , 121-n are not normally restored even after the preset number of repetition attempts, this operation is stopped to prevent an infinite restoration loop.

According to the present disclosure, even when an abnormality occurs in a sensing chip (sensing IC) due to a momentary surge current and/or strong electrical disturbance while a vehicle is in motion, there is an effect of being able to safely restore the sensing chip to normal by indirectly performing a hardware reset on the sensing chip.

In addition, there is an effect of being able to increase safety by preventing danger to vehicle drivers and reduce costs due to module replacement.

In the specification (particularly, in the claims) of the present disclosure, use of the term “above” and similar referential terms may refer to both the singular and the plural. In addition, when a range is stated in the present disclosure, the statement includes the disclosure to which individual values within the range are applied (unless there is a statement to the contrary), and is the same as a statement of the individual values constituting the range in the detailed description of the disclosure.

Unless there is a statement of an explicit order or a statement to the contrary regarding steps constituting the method according to the present disclosure, the steps may be performed in any appropriate order. The present disclosure is not necessarily limited by the described order of the steps. Use of any examples or illustrative terms (for example, and the like) in the present disclosure is merely to describe the present disclosure in detail, and unless limited by the claims, the scope of the present disclosure is not limited by the examples or illustrative terms. Further, those having ordinary skill in the art will appreciate that various modifications, combinations, and changes may be made according to design conditions and factors within the scope of the appended claims or their equivalents.

Therefore, the spirit of the present disclosure should not be limited to the above-described embodiments, and the scope of the appended claims described below as well as all scopes equivalent to or equivalently changed from the claims are within the scope of the spirit of the present disclosure.

What is claimed is:

1. A battery management system (BMS) comprising:
at least one sensing unit configured to sense a state of at least one battery module; and
a controller linked with the at least one sensing unit,
wherein, when an abnormality occurs in the at least one sensing unit, the controller performs a hardware reset on the at least one sensing unit.

2. The BMS according to claim 1, further comprising a communication unit configured to communicate with the at least one sensing unit and the controller and links the at least one sensing unit with the controller,
wherein, when an abnormality occurs in the at least one sensing unit, the controller performs a control operation so that the communication unit interrupts communication with the at least one sensing unit.

3. A Battery Management System (BMS) comprising:
at least one battery module;
a cell monitoring unit (CMU) comprising at least one sensing chip configured to sense a state of the at least one battery module; and
a battery management unit (BMU) comprising a communication chip configured to communicate with the at least one sensing chip, and a control chip linked with the at least one sensing chip through the communication chip,
wherein, when an abnormality occurs in the at least one sensing chip, the control chip performs a hardware reset on the at least one sensing chip.

4. The BMS according to claim 3, wherein, when an abnormality occurs in the at least one sensing chip, the control chip performs a control operation so that the communication chip interrupts communication with the at least one sensing chip.

5. A method of operating a Battery Management System (BMS), the method comprising:
detecting, by a controller, an abnormality of at least one sensing unit configured to sense a state of at least one battery module; and
performing, by the controller, a hardware reset on the at least one sensing unit.

6. The method according to claim 5, wherein the performing a hardware reset comprises performing, by the controller, a control operation to interrupt communication with the at least one sensing unit.

7. The method according to claim 5, further comprising performing, by the controller, a software reset on the at least one sensing unit.

8. A method of operating a Battery Management System (BMS), the method comprising:
detecting, by a control chip of a battery management unit (BMU), an abnormality of a sensing chip of at least one cell monitoring unit (CMU) configured to sense a state of at least one battery module; and
performing, by the control chip, a hardware reset on the sensing chip.

9. The method according to claim 8, wherein the performing a hardware reset comprises performing, by the control chip, a control operation to interrupt communication with the sensing chip.

10. The method according to claim 8, further comprising performing, by the control chip, a software reset on the sensing chip.
